(19) United States
(12) Patent Application Publication
(10) Pub. No.: US 2013/0162126 A1
(43) Pub. Date: Jun. 27, 2013

(54) COMPUTER SYSTEM

(71) Applicant: PO-KUANG SUE, Tu-Cheng (TW)

(72) Inventor: PO-KUANG SUE, Tu-Cheng (TW)

(73) Assignee: HON HAI PRECISION INDUSTRY CO., LTD., Tu-Cheng (TW)

(21) Appl. No.: 13/595,347

(22) Filed: Aug. 27, 2012

(30) Foreign Application Priority Data
Dec. 26, 2011 (TW) 100148719

(51) Int. Cl. H05K 7/02

(52) U.S. Cl. 312/223.2

(57) ABSTRACT

A computer system includes an enclosure, a bracket secured to the enclosure, and a power adaptor. The power adaptor is secured to the enclosure and includes a first sidewall and a second sidewall opposite to the first sidewall. A positioning piece is located on the first sidewall, and an installation piece is located on the second sidewall. The positioning piece is secured to the bracket, and the installation piece is secured to the enclosure.

### BACKGROUND

1. Technical Field

The present disclosure relates to computer systems, and particularly to a computer system with a power adaptor.

2. Description of Related Art

Notebook computers may include a main body and a power adaptor. The power adaptor is separate from the main body. Thus, users may find carrying the power adaptor to be inconvenient.

Therefore, there is room for improvement within the art.

### BRIEF DESCRIPTION OF THE DRAWINGS

Many aspects of the embodiments can be better understood with references to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is an exploded, isometric view of an embodiment of a computer system.

FIG. 2 is similar to FIG. 1, but viewed from a different aspect.

FIG. 3 is a partially assembled view of the computer system of FIG. 2.

FIG. 4 is an assembled view of the computer system of FIG. 1.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean at least one.

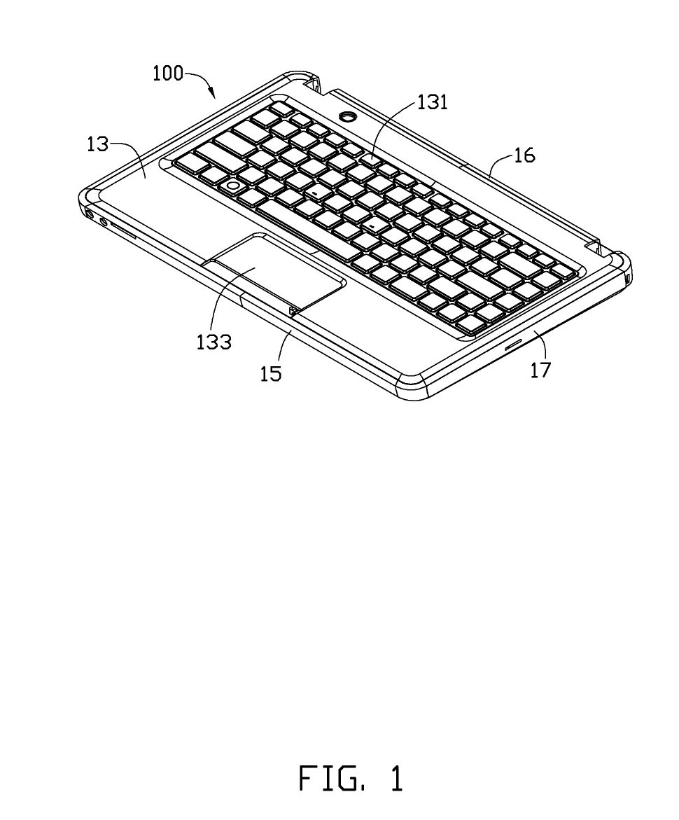

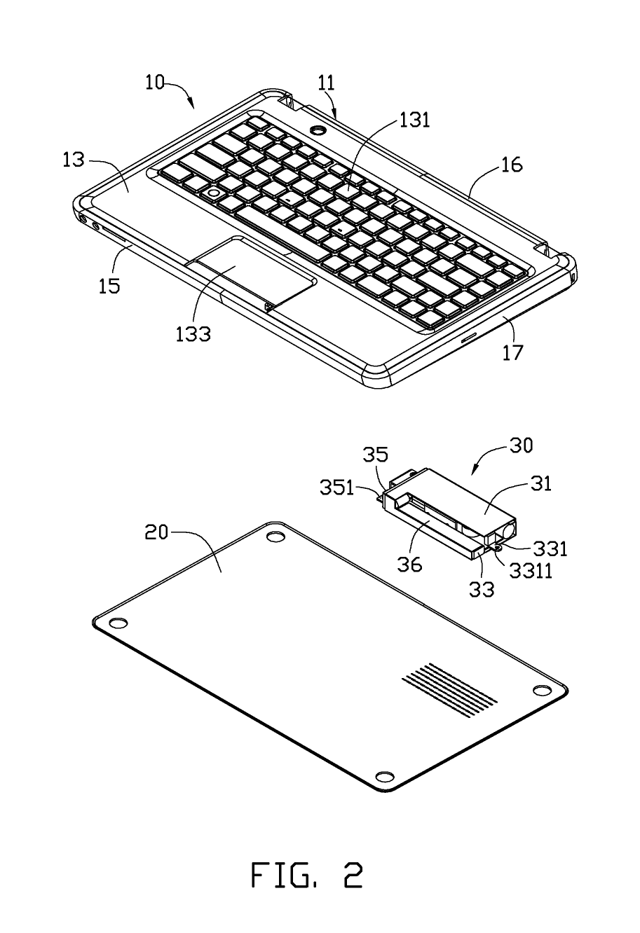

FIGS. 1-2 show a computer system in accordance with an embodiment. The computer system comprises a main body 100 and a power adaptor 30. In one embodiment, the computer system is a notebook computer.

The main body 100 comprises a base 10 and a bottom plate 20 attached to the base 10.

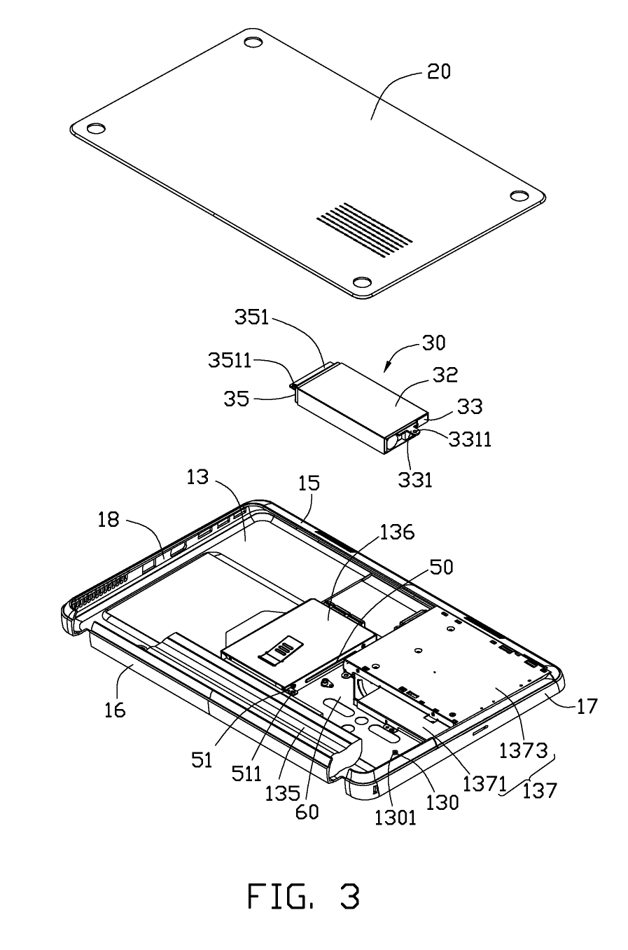

Referring to FIG. 2-3, the base 10 comprises an enclosure 11. The enclosure includes a cover plate 13, a front plate 15, a rear plate 16, a first side plate 17, and a second side plate 18. The front plate 15 and the rear plate 16 extend from opposite edges of the cover plate 13, respectively. The first side plate 17 and the second side plate 18 extend from another opposite edges of the cover plate 13, respectively. The front plate 15 is substantially perpendicularly connected to the first side plate 17.

A keyboard module 131 and a touching board 133 are located on a top surface of the cover plate 13. A battery 135, a disk driver 136, and a CD-ROM driver 137 are located on a bottom surface of the cover plate 13. The battery 135 abuts the rear plate 16, and one end of the battery 135 is adjacent to the first side plate 17. The disk driver 136 is fixed in middle of the cover plate 13. The CD-ROM driver 137 is located in a corner between the first side plate 17 and the front plate 15, and abutting the first side plate 17 and the front plate 15. The disk driver 136 is received in a bracket 50. A mounting piece 51 extends from the bracket 50 towards the first side plate 17. In one embodiment, the mounting piece 51 is substantially parallel to the cover plate 13. A mounting hole 511 is defined in the mounting piece 51. The CD-ROM driver 137 includes a receiving portion 1373 and an installation portion 1371 located on the receiving portion 1373. The receiving portion 1373 is configured to receive a CD disk. The installation portion 1371 protrudes from the receiving portion 1373 towards the rear plate 16 and is configured to fix a circuit board. The battery 135, the disk driver 136, and the CD-ROM driver cooperatively surround a receiving space 60. A positioning post 130 is defined in the cover plate 13 located in the receiving space 60. A positioning hole 1301 is defined in the positioning post 130.

The power adaptor 30 comprises a top wall 31, a bottom wall 32, a first sidewall 33, and a second sidewall 35. The top wall 31 is substantially parallel to the bottom wall 32, and the first sidewall 33 is substantially parallel to the second sidewall 35. The top wall 31 is substantially perpendicular to the first sidewall 33. A hollow portion 36, defined in the top wall 31, is configured to receive the installation portion 1371 of the CD-ROM driver. A positioning piece 331 extends outwards from the first sidewall 33. A locking hole 3311 is defined in the positioning piece 331. An installation piece 351 extends outwards from the second sidewall 35. An installation hole 3511 is defined in the installation piece 351. In one embodiment, the positioning piece 331 is substantially perpendicular to the first sidewall 33, and the installation piece 351 is substantially perpendicular to the second sidewall 35.

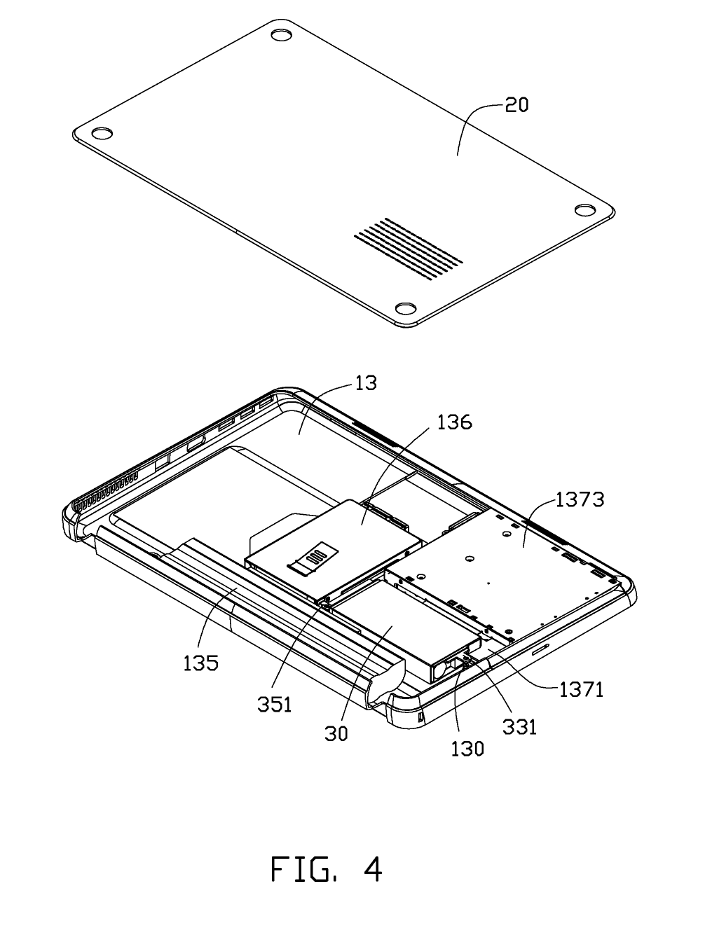

Referring to FIG. 4, in assembly, the power adaptor 30 is received in the receiving space 60. The hollow portion 36 is configured to receive a part of the installation portion 1371, for preventing the power adaptor 30 from being interfered by the CD-ROM driver 137. The positioning piece 331 abuts the positioning post 130 to align the locking hole 3311 with the positioning hole 1301, and a fastener, such as screw, is locked into the locking hole 3311 and the positioning hole 1301. The installation piece 351 abuts the mounting piece 51 to align the installation hole 3511 with the mounting hole 511, and a fastener is locked into the mounting piece 51 and the installation hole 3511. The power adaptor 30 is thereby secured to the main body 100.

It is to be understood, however, that even though numerous characteristics and advantages have been set forth in the foregoing description of embodiments, together with details of the structures and functions of the embodiments, the disclosure is illustrative only and changes may be made in detail, especially in the matters of shape, size, and arrangement of parts within the principles of the disclosure to the full extent indicated by the broad general meaning of the terms in which the appended claims are expressed.

What is claimed is:

1. A computer system comprising:
an enclosure;
a bracket secured to the enclosure; and
a power adaptor secured to the enclosure, the power adaptor comprising a first sidewall and a second sidewall, opposite to the first sidewall; a positioning piece located on the first sidewall, and an installation piece located on the second sidewall; and the positioning piece is secured to the bracket, and the installation piece is secured to the enclosure.

2. The computer system of claim 1, wherein a mounting piece is located on the bracket and defines a mounting hole, and an installation hole is defined in the installation piece; the mounting piece abuts the installation piece, and the installation hole is aligned with the mounting hole.

3. The computer system of claim 1, wherein the enclosure comprises a cover plate, a positioning post with a positioning hole is located on the cover plate, the positioning piece defines a locking hole and abuts the positioning post, and the locking hole is aligned with the positioning hole.

4. The computer system of claim 3, wherein both the positioning piece and the installation piece are substantially parallel to the cover plate.

5. The computer system of claim 3, wherein a battery and a CD-ROM driver are located on the cover plate; the bracket, and the battery and the CD-ROM driver cooperatively define a receiving space, and the power adapter is received in the receiving space.

6. The computer system of claim 5, wherein the enclosure further comprises a front plate and a side plate; and the front plate and the side plate respectively extend from adjacent edges of the cover plate, and the front plate is substantially perpendicular to the side plate and the cover plate.

7. The computer system of claim 6, wherein the CD-ROM driver is located on a corner between the front plate and the side plate, and the CD-ROM driver abuts the front plate and the side plate.

8. A computer system comprising:
an enclosure, the enclosure defines a receiving space;
a bracket secured to the enclosure; and
a power adaptor received in the receiving space, the power adaptor comprising a first sidewall and a second sidewall, opposite to the first sidewall; a positioning piece located on the first sidewall, and an installation piece located on the second sidewall; and the positioning piece is secured to the bracket, and the installation piece is secured to the enclosure.

9. The computer system of claim 8, wherein a mounting piece is located on the bracket and defines a mounting hole, an installation hole is defined in the installation piece, the mounting piece abuts the installation piece, and the installation hole is aligned with the mounting hole, for insertion of a fastener.

10. The computer system of claim 8, wherein the enclosure comprises a cover plate, a positioning post with a positioning hole is located on the cover plate, the positioning piece defines a locking hole and abuts the positioning post, and the locking hole is aligned with the positioning hole, for insertion of a fastener.

11. The computer system of claim 10, wherein the positioning piece and the installation piece are substantially parallel to the cover plate respectively.

12. The computer system of claim 10, wherein a battery and a CD-ROM driver are located on the cover plate, and the bracket, the battery and the CD-ROM driver cooperatively define the receiving space.

13. The computer system of claim 12, wherein the enclosure further comprises a front plate and a side plate; the front plate and the side plate are respectively extend from adjacent edges of the cover plate, and the front plate is substantially perpendicular to the side plate and the cover plate.

14. The computer system of claim 13, wherein the CD-ROM driver is located on a corner between the front plate and the side plate, and the CD-ROM driver abuts the front plate and the side plate respectively.
